(19) United States
(12) Patent Application Publication
(10) Pub. No.: US 2025/0210342 A1
(43) Pub. Date: Jun. 26, 2025

(54) SUBSTRATE PROCESSING APPARATUS AND A SUBSTRATE PROCESSING METHOD

(71) Applicant: SEMES CO., LTD., Cheonan-si (KR)

(72) Inventors: Do Hyeon YOON, Cheonan-si (KR); Mi So PARK, Cheonan-si (KR); Yong Joon IM, Yongin-si (KR); Hye Bin GWON, Cheonan-si (KR)

(73) Assignee: SEMES CO., LTD., Cheonan-si (KR)

(21) Appl. No.: 18/983,604

(22) Filed: Dec. 17, 2024

(30) Foreign Application Priority Data
Dec. 26, 2023 (KR) 10-2023-0191250

(51) Int. Cl. H01L 21/02

(52) U.S. Cl. CPC H01L 21/02101

(57) ABSTRACT

The present invention provides a substrate processing apparatus. In an embodiment, the substrate processing method includes: a loading step of loading a substrate into a treatment space provided in a chamber; a discharge step of discharging an atmosphere in the treatment space after the loading step; a pressurizing step of pressurizing the treatment space by supplying treatment fluid to the treatment space after the discharge step; a treatment step of treating the substrate in the treatment space using a fluid supplied to the treatment space after the pressurizing step; and a depressurizing step of depressurizing the treatment space after the treatment step.

### CROSS-REFERENCE TO RELATED APPLICATIONS

This application claims priority to and the benefit of Korean Patent Application No. 10-2023-0191250 filed in the Korean Intellectual Property Office on Dec. 26, 2023, the entire contents of which are incorporated herein by reference.

### TECHNICAL FIELD

The present invention relates to a substrate processing apparatus and a substrate processing method and, in more detail, a substrate processing apparatus and a substrate processing method by supplying supercritical fluid to the substrate.

### BACKGROUND ART

The manufacturing process of semiconductor devices includes a washing process of removing contaminants remaining on a substrate. In the washing process, a chemical process of removing contaminants on a substrate by supplying a chemical, a rinse process of removing the chemical on the substrate by supplying a rinse solution, and a drying process of drying the rinse solution remaining on the substrate sequentially proceed.

Recently, a technique of drying substrates using supercritical liquid when proceeding with a drying process is under development. According to this technique, it proceeds in the way of substituting an organic solvent for a rinse solution on a substrate and then dissolving the organic solvent into a supercritical fluid by supplying the supercritical fluid to separate the organic solvent from the substrate.

Since supercritical fluid maintains the characteristics at high critical pressure relative to the atmospheric pressure, a drying process is performed in a supercritical drying chamber that can maintain high pressure.

A common pipe simultaneously performs the function of a supply line that supplies treatment fluid to a drying chamber and the function of an exhaust line that exhausts the atmosphere of the drying chamber. However, after a supercritical treatment process is performed, contaminants such as an organic solvent or particles remain in a supercritical-treated chamber or a common pipe. When such residues are not discharged, they cause contamination of a substrate when the substrate is treated by supplying treatment fluid into a drying chamber through the common pipe.

### SUMMARY OF THE INVENTION

An objective of the present invention is to provide a substrate processing apparatus and a substrate processing method, the apparatus and method being able to prevent residues remaining in a treatment space in a drying chamber and pipes from contaminating a substrate.

Further, an objective of the present invention is to provide a substrate processing apparatus and a substrate processing method, the apparatus and method being able to prevent residues remaining in a treatment space in a drying chamber and pipes from contaminating a supply line that supply treatment fluid.

The objectives of the present invention are not limited thereto and other objectives not stated herein may be clearly understood by those skilled in the art from the following description.

The present invention provides a substrate processing apparatus. In an embodiment, the substrate processing method includes: a loading step of loading a substrate into a treatment space provided in a chamber; a discharge step of discharging an atmosphere in the treatment space after the loading step; a pressurizing step of pressurizing the treatment space by supplying treatment fluid to the treatment space after the discharge step; a treatment step of treating the substrate in the treatment space using a fluid supplied to the treatment space after the pressurizing step; and a depressurizing step of depressurizing the treatment space after the treatment step.

In an embodiment, a common pipe may be connected to the chamber, the common pipe may be connected with a first supply line supplying the treatment fluid to the treatment space and an exhaust line exhausting the atmosphere of the treatment space, and exhaust of the treatment space may be performed through the common pipe in the discharge step.

In an embodiment, the discharge step may include an opening step of opening an exhaust valve installed on the exhaust line and a first supply valve installed on the first supply line, and the treatment fluid supplied through the first supply line may be discharged to the exhaust line in the opening step.

In an embodiment, the discharge step may further include a pre-opening step of opening the exhaust valve in advance before the opening step, and atmospheres of the treatment space and the common pipe may be discharged through the exhaust line in the pre-opening step.

In an embodiment, the pressurizing step may be performed by closing the exhaust valve and supplying the treatment fluid to the treatment space from the first supply line after the discharge step, and the treatment fluid may be supplied through the common pipe.

In an embodiment, the pressurizing step may close the first supply valve and may supply the treatment fluid to the treatment space through a second supply line connected to the chamber after supplying the treatment fluid to the treatment space from the first supply line.

In an embodiment, exhaust of the treatment space may be performed through the common pipe in the depressurizing step.

In an embodiment, the common pipe may be connected to a bottom surface of the chamber, the first supply line is a lower supply line supplying the treatment fluid to a lower portion of the treatment space, and the second supply line may be an upper supply line supplying the treatment fluid to an upper portion of the treatment space.

In an embodiment, the treatment fluid may be fluid in a supercritical state, and the treatment of a substrate may be a process of drying a substrate using the fluid in a supercritical state.

Further, the present invention provides a substrate processing apparatus. In an embodiment, the substrate processing apparatus includes: a chamber having a treatment space therein; a supporting unit supporting a substrate in the treatment space; a supply unit supplying treatment fluid to the treatment space; an exhaust unit exhausting an atmosphere in the treatment space; and a control unit controlling the supply unit and the exhaust unit, wherein the supply unit includes a first supply line connected to a lower portion of the chamber and a second supply line connected to an upper portion of the chamber, the exhaust unit includes: an exhaust line exhausting an atmosphere of the chamber; and an exhaust valve installed on the exhaust line, and the control unit controls the supply unit and the exhaust unit to sequentially perform: a loading step of loading the substrate into the treatment space; a discharge step of discharging an atmosphere in the treatment space; a pressurizing step of pressurizing the treatment space by supplying treatment fluid to the treatment space; a treatment step of treating the substrate in the treatment space using the fluid supplied to the treatment space; and a depressurizing step of exhausting the fluid from the treatment space.

In an embodiment, a common pipe may be connected to the chamber and the chamber may be connected with the first supply line and the exhaust line through the common pipe.

In an embodiment, the control unit may open an exhaust valve installed on the exhaust line and a first supply valve installed on the first supply line in the discharge step, and may perform control such that the treatment fluid supplied through the first supply line is discharged to the exhaust line.

In an embodiment, the control unit may open the exhaust valve in advance before opening the first supply valve in the discharge step, and may perform control such that atmospheres of the treatment space and the common pipe are discharged through the exhaust line.

In an embodiment, the control unit may perform control such that the pressurizing step is performed by closing the exhaust valve and supplying the treatment fluid to the treatment space from the first supply line after the discharge step.

In an embodiment, the control unit may close the first supply valve and perform control such that the treatment fluid is supplied to the treatment space through a second supply line connected to the chamber after supplying the treatment fluid to the treatment space from the first supply line in the pressurizing step.

Further, the present invention provides a substrate processing method. In an embodiment a substrate processing method disposes a substrate into a treatment space provided in a supercritical chamber and treats the substrates by supplying treatment fluid in a supercritical state to the treatment space, and the method includes: a loading step of loading a substrate into the treatment space; a discharge step of discharging an atmosphere in the treatment space; a pressurizing step of pressurizing the treatment space by supplying treatment fluid to the treatment space; a treatment step of treating the substrate in the treatment space using a fluid supplied to the treatment space; and a depressurizing step of exhausting the fluid from the treatment space, wherein a common pipe is connected to the treatment space, the common pipe is connected with a supply line supplying the treatment fluid to the treatment space and an exhaust line exhausting the atmosphere of the treatment space, and discharge and exhaust of the treatment space are performed through the common pipe in the discharge step and the depressurizing step.

In an embodiment, the discharge step may include an opening step of opening an exhaust valve installed on the exhaust line and a supply valve installed on the supply line, and the treatment fluid supplied through the supply line may be discharged to the exhaust line in the opening step.

In an embodiment, the discharge step may further include a pre-opening step of opening the exhaust valve in advance before the opening step, and atmospheres of the treatment space and the common pipe may be discharged through the exhaust line in the pre-opening step.

In an embodiment, the pressurizing step may be performed by closing the exhaust valve and supplying the treatment fluid to the treatment space from the supply line after the discharge step, and the treatment fluid may be supplied through the common pipe.

In an embodiment, the treatment fluid may be fluid in a supercritical state, and the treatment of a substrate may be a process of drying a substrate using the fluid in a supercritical state.

According to an embodiment of the present disclosure, it is possible to minimize contamination of a substrate due to residues in the common pipe and the treatment space by discharging the residue in the common pipe and the treatment space through the exhaust line.

Further, according to an embodiment of the present disclosure, it is possible to prevent contamination of a supply line for treatment fluid due to residues in the common pipe and the treatment space.

Effects of the present invention are not limited to those described above and effects not stated above will be clearly understood to those skilled in the art from the specification and the accompanying drawings.

### BRIEF DESCRIPTION OF THE DRAWINGS

FIG. 1 is a plan view schematically showing a substrate processing apparatus according to an embodiment of the present invention.

FIG. 2 is a view schematically showing an embodiment of the liquid treatment chamber of FIG. 1.

FIG. 3 is a view schematically showing an embodiment of the drying chamber of FIG. 1.

FIG. 4 is a flowchart of a substrate processing method in a drying chamber according to the embodiment of FIG. 3.

FIG. 5 shows the appearance of the drying chamber when the loading step of FIG. 4 proceeds.

FIG. 6 shows the state of the drying chamber in the pre-opening step of FIG. 4.

FIG. 7 shows the state of the drying chamber in the opening step of FIG. 4.

FIGS. 8 to 11 show the state of the drying chamber in the pressurizing step, the depressurizing step, and the unloading step of FIG. 4.

Various features and advantages of the non-limiting exemplary embodiments of the present specification may become apparent upon review of the detailed description in conjunction with the accompanying drawings. The attached drawings are provided for illustrative purposes only and should not be construed to limit the scope of the claims. The accompanying drawings are not considered to be drawn to scale unless explicitly stated. Various dimensions in the drawing may be exaggerated for clarity.

### DETAILED DESCRIPTION

Example embodiments will now be described more fully with reference to the accompanying drawings. Example embodiments are provided so that this disclosure will be thorough and will fully convey the scope to those who are skilled in the art. Numerous specific details are set forth such as examples of specific components, apparatuses, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

The terminology used herein is for the purpose of describing particular example embodiments only and is not intended to be limiting. As used herein, the singular forms “a,” “an,” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

When an element or layer is referred to as being “on,” “engaged to,” “connected to,” or “coupled to” another element or layer, it may be directly on, engaged, connected or coupled to the other element or layer, or intervening elements or layers may be present. In contrast, when an element is referred to as being “directly on,” “directly engaged to,” “directly connected to,” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

Spatially relative terms, such as “inner,” “outer,” “beneath,” “below,” “lower,” “above,” “upper,” and the like, may be used herein for ease of description to describe one element or feature's relationship to another element(s) or feature(s) as illustrated in the figures. Spatially relative terms may be intended to encompass different orientations of the apparatus in use or operation in addition to the orientation depicted in the figures. For example, if the apparatus in the figures is turned over, elements described as “below” or “beneath” other elements or features would then be oriented “above” the other elements or features. Thus, the example term “below” can encompass both an orientation of above and below. The apparatus may be otherwise oriented (rotated 90 degrees or at other orientations) and the spatially relative descriptors used herein interpreted accordingly.

When the term “same” or “identical” is used in the description of example embodiments, it should be understood that some imprecisions may exist. Thus, when one element or value is referred to as being the same as another element or value, it should be understood that the element or value is the same as the other element or value within a manufacturing or operational tolerance range (e.g., ±10%).

When the terms “about” or “substantially” are used in connection with a numerical value, it should be understood that the associated numerical value includes a manufacturing or operational tolerance (e.g., ±10%) around the stated numerical value. Moreover, when the words “generally” and “substantially” are used in connection with a geometric shape, it should be understood that the precision of the geometric shape is not required but that latitude for the shape is within the scope of the disclosure.

Unless otherwise defined, all terms (including technical and scientific terms) used herein have the same meaning as commonly understood by one of ordinary skill in the art to which example embodiments belong. It will be further understood that terms, including those defined in commonly used dictionaries, should be interpreted as having a meaning that is consistent with their meaning in the context of the relevant art and will not be interpreted in an idealized or overly formal sense unless expressly so defined herein.

An apparatus for removing an organic solvent remaining on a substrate using supercritical fluid is exemplarily described in this embodiment. However, this embodiment is not limited thereto and may be applied to other kinds of apparatuses for treating a substrate in which organic matters may remain in a chamber after a process of treating a substrate is performed.

Hereafter, an example of a substrate processing apparatus of the present invention is described in detail with reference to the accompanying drawings.

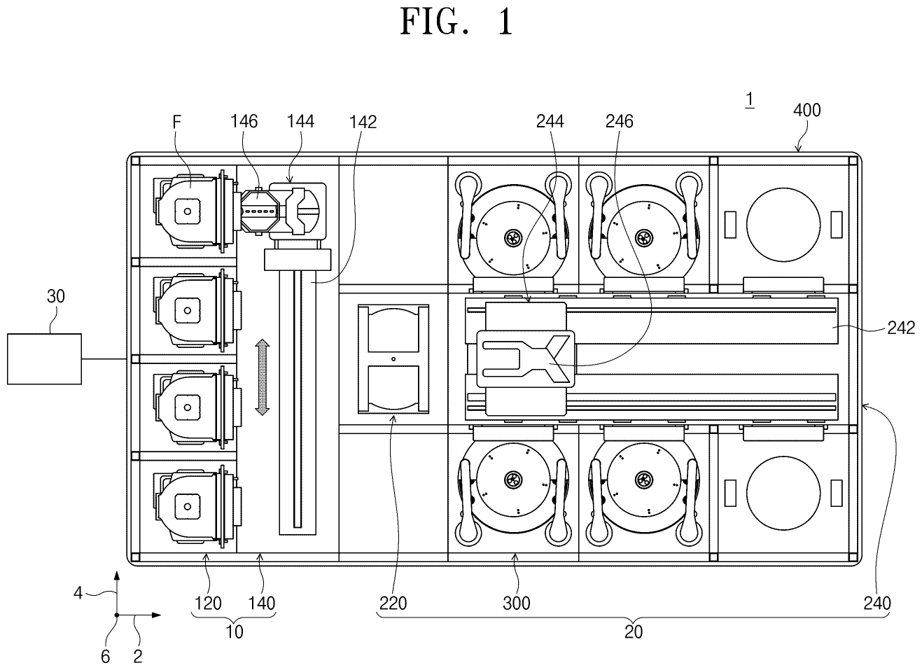

FIG. 1 is a plan view schematically showing a substrate processing apparatus according to an embodiment of the present invention. Referring to FIG. 1, an apparatus 1 for treating a substrate includes an index module 10 and a treating module 20. According to an embodiment, the index module 10 and the treating module 20 are disposed in one direction. Hereafter, the direction in which the index module 10 and the treating module 20 are disposed is defined as a first direction 2. When seen from above, a direction perpendicular to the first direction 2 is defined as a second direction 4 and a direction perpendicular to a plane including both of the first direction 2 and the second direction 4 is defined as a third direction 6.

The index module 10 transfers substrates W from containers F having the substrates W therein to the treating module 20 treating the substrates W. The index module 10 puts substrates W treated by the treating module 20 into the containers F. The longitudinal direction of the index module 10 is provided in the second direction 4. The index module 10 has a load port 120 and an index frame 140.

Containers F having substrates W therein are seated in the load port 120. The load port 120 is positioned at the opposite side to the treating module 20 with the index frame 140 therebetween. A plurality of load ports 120 may be provided. The plurality of load ports 120 may be disposed in one line in the second direction 4. The number of the load ports 120 may be increased or decreased, depending on the process efficiency, a footprint condition, etc. of the treating module 20.

A plurality of slots (not shown) is formed at the container F. The slots (not shown) can receive substrates W disposed in parallel with the ground. The container F may be a container for sealing such as a Front Opening Unified Pod (FOUP). The container F may be placed onto the load port 120 by a worker or a conveying device (not shown) such as an overhead transfer, an overhead conveyor, or an automatic guided vehicle.

An index rail 142 and an index robot 144 are provided in the index frame 140. The index rail 142 is provided in the index frame 140 with the longitudinal direction thereof in the second direction 4. The index robot 144 can transfer substrates W. The index robot 144 can transfer substrates W between the index module 10 and a buffer unit 220 to be described below.

The index robot 144 includes an index hand 146. A substrate 144 is seated in the index hand 146. The index hand 146 may be provided on the index rail 142 to be movable in the second direction 4. Accordingly, the index hand 146 can move forward and backward along the index rail 142. Further, the index hand 146 may be provided to be rotatable around the third direction 6. Further, the index hand 146 may be provided to be vertically movable in the third direction 6. A plurality of index hands 146 may be provided. The plurality of index hands 146 may be provided to be spaced in the up-down direction. The plurality of index hands 146 can move forward and backward and rotate independently from each other.

A controller 30 can control the apparatus 1 for treating a substrate. The control unit 30 may include: a process controller that is a microprocessor (computer) that performs control of the apparatus 1 for treating a substrate; a user interface that is a keyboard through which an operator performs command input operation, etc. to manage the apparatus 1 for treating a substrate, a display that visualizes and displays the operation situation of the apparatus 1 for treating a substrate, etc.; and a memory that stores a control program for performing treatment, which is performed in the apparatus 1 for treating a substrate, under control of the process controller, a program for performing treatment on each component in accordance with various data and treatment conditions, that is, a treatment recipe. Further, the user interface and the memory may be connected to the process controller. The treatment recipe may be stored in a memory medium of the memory unit and the memory medium may be a hard disk and may be a portable disc such as a CD-ROM and a DVD, and a semiconductor memory such as a flash memory.

The control unit 30 can control the apparatus 1 for treating a substrate to be able to perform the substrate processing method to be described below. For example, the control unit 30 can perform the substrate processing method to be described below by controlling the components provided in a drying chamber 400 to be described below.

For example, the control unit 30 can control a transfer unit 244 and a washing unit 500 to be described below such that the washing unit 500 washes a treatment space 421.

The treating module 20 includes a buffer unit 220, a transfer frame 240, a liquid treatment chamber 300, and a drying chamber 400. The buffer unit 220 provides a buffer space in which substrates W that are loaded into the treating module 20 and substrates W that are unloaded from the treating module 20 temporarily stay. The transfer frame 240 provides a transfer space for transferring substrates W between the buffer unit 220, the liquid treatment chamber 300, and the drying chamber 400.

The liquid treatment chamber 300 can perform a liquid treatment process of liquid treatment on substrates W by supplying liquid onto the substrates W. The drying chamber 400 can perform drying treatment that removes liquid remaining on substrates W. The liquid treatment chamber 300 and the drying chamber 400 can perform a washing process. The washing process can be sequentially performed in the liquid treatment chamber 300 and the drying chamber 400. For example, substrates W can be treated in the liquid treatment chamber 300 by supplying a chemical, a rinse solution, and/or an organic solvent to the substrates W. For example, drying treatment that removes liquid remaining on substrates W using supercritical fluid can be performed in the drying chamber 400.

The buffer unit 220 may be disposed between the index frame 140 and the transfer frame 240. The buffer unit 220 may be positioned at an end of the transfer frame 240. A slot (not shown) in which a substrate W is placed is provided in the buffer unit 220. A plurality of slots (not shown) is provided. The plurality of slots (not shown) may be disposed to be spaced apart from each other in the third direction 6. The buffer unit 220 is open on the front face and the rear face. The front face may be a surface that faces the index module 20 and the rear face may be a surface that faces the transfer frame 240. The index robot 144 can approach the buffer unit 220 through a front face and the transfer unit 244 to be described below can approach the buffer unit 220 through a rear face.

The longitudinal direction of the transfer frame 240 may be provided in the first direction 2. The liquid treatment chamber 300 and the drying chamber 400 may be disposed at both sides of the transfer frame 240. The liquid treatment chamber 300 and the drying chamber 400 may be disposed on sides of the transfer frame 240. The transfer frame 240 and the liquid treatment chamber 300 may be disposed in the second direction 4. Further, the transfer frame 240 and the drying chamber 400 may be disposed in the second direction 4.

According to an embodiment, liquid treatment chambers 300 are disposed at both sides of the transfer frame 240 and drying chambers 400 are disposed at both sides of the transfer frame 240. The liquid treatment chambers 300 may be disposed at positions close to the buffer unit 220 in comparison to the drying chambers 400. The liquid treatment chambers 300 may be provided in an array of A×B (A and B are each a natural number of 1 or more) in the first direction 2 and the third direction 6, respectively, at a side of the transfer frame 240. In this case, A is the number of the liquid treatment chambers 300 provided in a line in the first direction 2 and B is the number of the liquid treatment chambers 300 provided in a line in the third direction 6. For example, when four liquid treatment chambers 300 are provided at a side of the transfer frame 240, the liquid treatment chambers 300 may be disposed in an array of 2×2. The number of the liquid treatment chamber 300 may be increased or decreased. Unlike the above description, the liquid treatment chambers 300 may be provided only at a first side of the transfer frame 240 and only the drying chambers 400 may be disposed at a second side opposite to the first side. Further, the liquid treatment chambers 300 and the drying chambers 400 may be provided in a single layer at one side or both sides of the transfer frame 240.

The transfer frame 240 has the guide rail 242 and the transfer unit 244. The guide rail 242 is provided in the transfer frame 240 with the longitudinal direction thereof in the first direction 2. The transfer unit 244 may be provided on the guide rail 242 to be movable in the first direction 2. The transfer unit 244 transfers substrates W between the buffer unit 220, the liquid treatment chamber 300, and the drying chamber 400.

The transfer unit 244 includes a transfer hand 246 on which a substrate W is placed. The transfer hand 246 may be provided on the guide rail 242 to be movable in the first direction 2. Accordingly, the transfer hand 246 can move forward and backward along the guide rail 242. Further, the transfer hand 246 may be provided to be able to rotate around the third direction 6 and move in the third direction 6. A plurality of transfer hands 246 may be provided. The plurality of transfer hands 246 may be provided to be spaced in the up-down direction. The plurality of transfer hands 246 can move forward and backward and rotate independently from each other.

The liquid treatment chamber 300 performs a process of liquid treatment on substrates W. For example, the liquid treatment chamber 300 may be a chamber that performs a washing process of removing process byproducts sticking to substrates W. The liquid treatment chambers 300 may have different structures, depending on the kinds of processes of treating substrates W. Unlike, the liquid treatment chambers 300 may have the same structure.

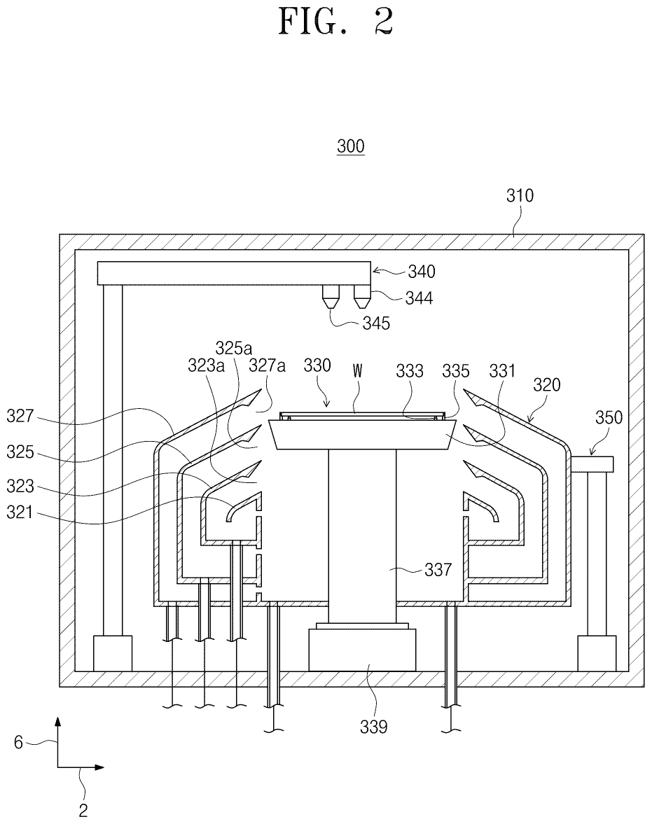

FIG. 2 is a view schematically showing an embodiment of the liquid treatment chamber of FIG. 1. Referring to FIG. 2, the liquid treatment chamber 300 includes a housing 310, a treatment container 320, a supporting unit 330, and a liquid supply unit 340.

The housing 310 has an internal space. The housing 310 is provided substantially in a rectangular prism shape. An opening (not shown) is formed on a side of the housing 310. The opening (not shown) functions as an entrance through which substrates W are loaded into the internal space of the housing 310 or unloaded from the internal space by the transfer unit 244. The treatment container 320, the supporting unit 330, and the liquid supply unit 340 are disposed in the internal space of the housing 310.

The treatment container 320 has a treatment space with an open top. The treatment container 320 may be a bowl having a treatment space. The treatment container 320 may be provided to surround a treatment space. The treatment space of the treatment container 320 is provided as a space in which the supporting unit 330 to be described below supports and rotates substrates W. The treatment space is provided as a space in which liquid is supplied onto substrates W and the substrates W are treated.

According to an embodiment, the treatment container 320 may have a guide wall 321 and a plurality of recovery tubs 323, 325, and 327. The recovery tubs 323, 325, and 327 recover different liquids from liquids used to treat substrates W. The recovery tubs 323, 325, and 327 each may have a recovery space for recovering liquid used to treat substrates W.

The guide wall 321 is provided in a ring shape surrounding the recovery tubs 323, 325, and 327 and the supporting unit 330. When liquid is supplied to a substrate W, liquid that is scattered by rotation of the substrate W can enter the recovery spaces through inlets of the recovery tubs 323, 325, and 327 to be described below. Different kinds of liquids can enter the recovery tubs 323, 325, and 327, respectively.

The supporting unit 330 supports and rotates substrates W in the treatment space. The supporting unit 330 may have a spin chuck 331, a supporting pin 333, a chuck pin 335, a rotary shaft 337, and an actuator 339.

The spin chuck 331 has an upper surface that is provided substantially in a circular shape when seen from above. The upper surface of the spin check 331 may have a diameter larger than substrates W.

A plurality of supporting pins 333 is provided. The supporting pins 333 are disposed on the upper surface of the spin chuck 331. The supporting pins 333 are disposed with regular intervals at the edge of the upper surface of the spin chuck 331. The supporting pins 333 protrude upward from the upper surface of the spin chuck 331. The supporting pins 333 are disposed to have entirely a ring shape through a combination thereof. The supporting pins 333 support the edge region of the rear face of a substrate W such that the substrate W is spaced a predetermined distance apart from the upper surface of the spin chuck 331.

A plurality of chuck pins 335 is provided. The chuck pins 335 are disposed far from the center region of the spin chuck 331 in comparison to the supporting pins 333. The chuck pins 335 protrude upward from the upper surface of the spin chuck 331. When a substrate W is rotated, the chuck pins 335 support the side region of the substrate W to prevent lateral separation from the position.

The rotary shaft 337 is coupled to the spin chuck 331. The rotary shaft 337 is coupled to the bottom surface of the spin chuck 331. The rotary shaft 337 may be provided such that the longitudinal direction thereof is placed in the third direction 6. The rotary shaft 337 is provided to be rotatable by power from the actuator 339. The rotary shaft 337 is rotated by the actuator 339 and the spin chuck 331 is rotated through the rotary shaft 337. The actuator 339 rotates the rotary shaft 337. The actuator 339 can change the rotation speed of the rotary shaft 337. The actuator 339 may be a motor that provides a driving force. However, the actuator is not limited thereto and may be modified and provided as well-known devices that provide a driving force.

The liquid supply unit 340 supplies liquid to substrates W. The liquid supply unit 340 supplies liquid to a substrate W supported on the supporting unit 330. A plurality of kinds of liquid is provided as the liquid that is supplied to substrates W by the liquid supply unit 340. According to an embodiment, the liquid that is supplied to substrates W by the liquid supply unit 340 may include a first liquid and a second liquid. The first liquid and the second liquid can provide different kinds of liquid. The first liquid and the second liquid may be sequentially supplied to substrates W.

A first liquid supply nozzle 344 supplies the first liquid to substrates W. The first liquid supply nozzle 344 can supply the first liquid onto a substrate W supported on the supporting unit 330. A second liquid supply nozzle 345 supplies the second liquid to substrates W. The second liquid supply nozzle 345 can supply the second liquid onto a substrate W supported on the supporting unit 330.

The first liquid and the second liquid may be any one of a chemical, a rinse solution, and an organic solvent. For example, the chemical may include Diluted Sulfuric acid Peroxide (H₂SO₄), phosphoric acid (P₂O₅), hydrofluoric acid (HF), and ammonium hydroxide (NH₄OH). For example, the rinse solution may include pure water or deionized water (DIW). For example, the organic solvent may include alcohol such as Isopropyl Alcohol (IPA). According to an embodiment, the first liquid may be liquid that removes films or foreign substances remaining on substrates W. According to an embodiment, the second liquid may be liquid that neutralizes the first liquid. According to an embodiment, the second liquid may be liquid that is easily dissolved in drying fluid. Further, the second liquid may be liquid that is easily dissolved in supercritical liquid that is used in the drying chamber 400 to be described below. According to an embodiment, the second liquid may be liquid that is more easily dissolved in the drying liquid to be described below than the first liquid.

An elevation unit 350 is disposed in the internal space of the housing 310. The elevation unit 350 adjusts the relative height between the treatment container 320 and the supporting unit 330. The elevation unit 350 can straightly move the treatment container 320 in the third direction 6. Accordingly, the heights of the recovery tubs 323, 325, and 327 that recover liquids are changed, depending on the kinds of liquids that are supplied to substrates W, so it is possible to separately recover liquids. Unlike the above description, the treatment container 320 may be fixed, and the elevation unit 350 may change the relative height between the supporting unit 330 and the treatment container 320 by moving the supporting unit 330 in the up-down direction.

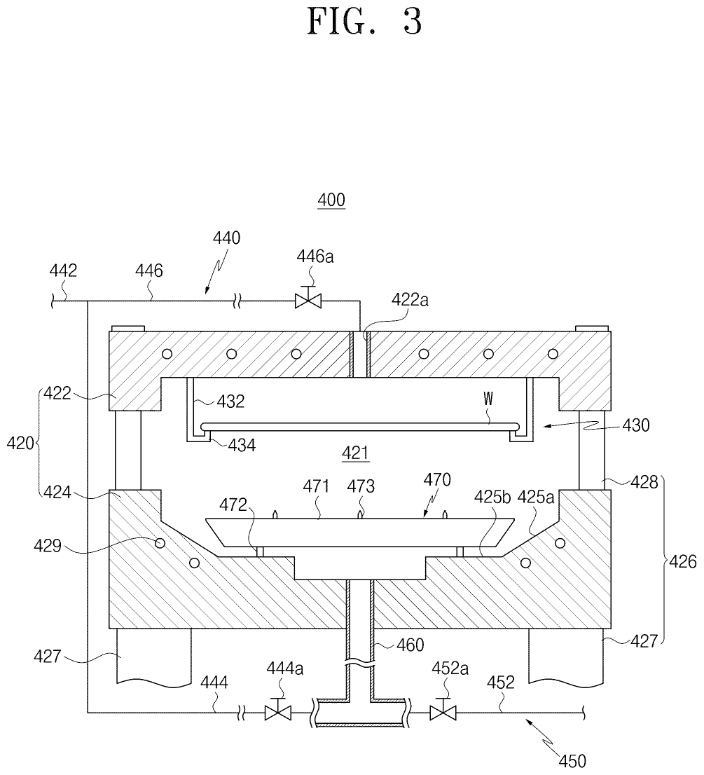

FIG. 3 is a view schematically showing an embodiment of the drying chamber of FIG. 1. Referring to FIG. 3, the drying chamber 400 may include a chamber body 420, a supporting unit 430, a supply unit 440, an exhaust unit 450, a common pipe 460, a filler member 470, and a control unit 480.

The chamber body 420 provides a treatment space 421 in which drying treatment is performed on substrates W. The chamber body 420 may include an upper body 422, a lower body 424, and an elevation member 426.

The upper body 422 and the lower body 424 provide the treatment space 421 by combining with each other. The upper body 422 is positioned higher than the lower body 424. A supply port 422a may be provided at the upper body and the common pipe 460 may be provided at the lower body. According to an embodiment, the supply port 422a may be formed in the center region of the upper body 422 when seen from above. The common pipe 460 may be formed in the center region of the lower body 424 when seen from above. The common pipe 460 will be described below.

The position of the upper body 422 may be fixed and the lower body 424 may be moved up and down by the elevation member 426 to be described below. When the lower body 424 is moved down and spaced from the upper body 422, the treatment space 421 is opened. When the treatment space 421 is opened, a substrate W can be loaded into the treatment space 421 or a substrate W can be unloaded out of the treatment space 421. A substrate W that is loaded into the treatment space 421 may be a substrate W that has undergone liquid treatment in the liquid treatment chamber 300.

When the lower body 424 is moved up and brought in close contact with the upper body 422, the treatment space 421 is sealed. When the treatment space 421 is sealed, drying treatment can be performed on a substrate W by supplying supercritical fluid.

The elevation member 426 moves up and down the lower body 424. The elevation member 426 may include an actuator that moves up and down the lower body 424. For example, the elevation member 426 may include a cylinder 427. The elevation member can keep pressing the lower body to keep the upper body 422 and the lower body 424 in close contact with each other while drying treatment is performed.

Selectively, a clamping unit (not shown) that clamps the upper body and the lower body to prevent the treatment space from being opened by the internal pressure of the treatment space when a process proceeds may be provided.

According to an embodiment of the present invention described above, it was exemplified that the lower body 424 seals the treatment space 421 by moving in the up-down direction, but the present invention is not limited thereto. For example, the upper body 422 may be moved in the up-down direction and the position of the lower body 424 may be fixed.

Heaters 429 may be installed in the chamber body 420. According to an embodiment, the heaters 429 may be embedded in the wall of at least any one of the upper body 422 and the lower body 424. The heaters 429 can maintain treatment fluid supplied in the treatment space 421 in the phase of supercritical fluid by heating the treatment fluid over critical temperature, or when treatment fluid liquefies, the heaters 429 can heat again the treatment fluid back into the phase of supercritical fluid.

The supporting unit 430 supports substrates W in the treatment space 421. The supporting unit 430 may be fixed to the bottom surface of the upper body 422. The supporting unit 430 may have a fixing rod 432 and a holder 434.

The fixing rods 432 may be fixed to the upper body 422 to protrude downward from the lower surface of the upper body 422. The longitudinal direction of the fixing rod 432 may be provided in the up-down direction. A plurality of fixing rods 432 may be provided. The plurality of fixing rods 432 is positioned to be spaced apart from each other. The plurality of fixing rods 432 is disposed at positions where they do not interfere with a substrate W when the substrate W is loaded into or unloaded out of the space surrounded by the plurality of fixing rods 432. The holder 434 is coupled to the fixing rods 432.

The holder 434 extends from the fixing rods 432. The holder 434 may extend toward the space surrounded by the fixing rods 432 from the lower ends of the fixing rods 432. The holders 434 extend upward from the extension ends, thereby being able to support the edge region of the rear of a substrate W. According to an embodiment, the rear of a substrate W may be a surface without a pattern and the top surface of the substrate W may be a surface with a pattern. By the structure described above, the edge region of a substrate W loaded into the treatment space 421 can be placed on the holders 432. Further, the entire region of the top surface of a substrate W, the center region of the lower surface of the substrate W, and portions of the edge region of the lower surface of the substrate W can be exposed to treatment fluid supplied to the treatment space 421.

The supply unit 440 supplies treatment fluid to the treatment space 421. According to an embodiment, carbon dioxide (CO₂) gas in a supercritical state may be used as the treatment fluid. Carbon dioxide can enter a supercritical state by temperature over 30° C. and pressure over 7.4 MPa. Hereafter, it is exemplarily described that treatment fluid is carbon dioxide gas. Treatment fluid according to an embodiment can be supplied to the treatment space 421 in a supercritical state. However, the treatment fluid is not limited thereto and may be supplied to the treatment space 421 in a gas state and the phase thereof may be changed into a supercritical state in the treatment space 421. According to an example, the supply unit 440 has a main supply line 442, a first supply line 444, and a second supply line 446. The first supply line 444 and the second supply line 446 diverge from the main supply line 442. The first supply line 444 is connected with the common pipe 460 to be described below, thereby supplying treatment fluid from under a substrate W placed on the supporting unit 430. A first supply valve 444a is installed on the first supply line 444. The first supply valve 444a opens/closes the first supply line 444. The second supply line 446 is connected to the supply port 422a, thereby supplying treatment fluid from above a substrate W placed on the supporting unit 430. A second supply valve 446a is installed on the second supply line 446. The second supply valve 446a opens/closes the second supply line 446.

The exhaust unit 450 exhausts the atmosphere of the treatment space 421. The exhaust unit 450 includes an exhaust line 452 and an exhaust valve 452a. The exhaust valve 452a is installed on the exhaust line 452 and opens/closes the exhaust line 452. The exhaust line 452 is connected with the common pipe 460 formed in the lower body 424. Treatment fluid flowing in the treatment space 421 is discharged out of the chamber body 420 through the exhaust line 452.

An end of the common pipe 460 is connected with the treatment space 421 and the other end is connected with the first supply line 444 and the exhaust line 452. Accordingly, the common pipe 460 can supply treatment fluid, which is supplied from the first supply line 444, to the treatment space 421. Further, the common pipe 460 can exhaust the atmosphere of the treatment space 421 through the exhaust line 452.

The filler member 470 is positioned in the treatment space 421. The filler member 470 is positioned under the supporting unit 430. When seen from above, the filler member 470 may be disposed to overlap the common pipe 460 formed in the lower body 424. The filler member 470 can prevent treatment fluid supplied through the common pipe 460 from being directly discharged toward a substrate W and damaging the substrate W.

The filler member 470 includes a filler 471, a support 472, and a supporting pin 473.

The filler 471 is provided in a plate shape having a predetermined thickness. The filler 471 may be solid or hollow. The filler 471 has a top surface, a bottom surface, and a side surface. The top surface is disposed in parallel with the bottom surface while facing the bottom surface. The top surface has a larger area than the bottom surface. The top surface of the filler 471 can maintain a preset gap from the lower surface of a substrate W supported by the holders 434 with the inside of the chamber body 420 sealed. The bottom surface of the filler 471 is disposed to face a first floor surface 425b of the chamber body 420. The bottom surface is spaced apart from the first floor surface 425b with a predetermined gap therebetween. The filler 471 can be supported by the support 472 to be spaced apart from the first floor surface 425b of the chamber body 420. The support 472 may be provided in a rod shape. A plurality of supports 472 may be provided. The supports 472 are disposed to be spaced a predetermined distance apart from each other. The side surface of the filler 471 connects the top surface and the bottom surface of the filler 471. The side surface of the filler 471 extends from the bottom surface and inclines upward such that the cross-sectional area of the filler gradually increases toward the upper end. The side surface of the filler 471 may be provided in parallel with an inclined surface 425a. The side surface of the filler 471 may be provided such that a partial region faces the inclined surface 425a. The side surface of the filler 471 is spaced apart from the inclined surface 425a with a predetermined gap therebetween.

The filler 471 includes a plurality of supporting pins 473 provided on the top surface. The plurality of supporting pins 473 can support the lower surface of a substrate W with the inside of the chamber body 420 sealed.

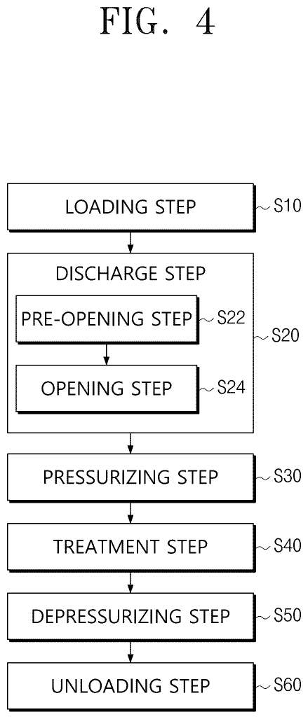

FIG. 4 is a flowchart of a substrate processing method in a drying chamber according to the embodiment of FIG. 3.

Referring to FIG. 4, a substrate processing method according to an embodiment of the present invention includes a loading step S10, a discharge (exhaust step) S20, a pressurizing step 30, a treatment step S40, a depressurizing step S50, and an unloading step S60. Further, the discharge step S20 includes a pre-opening step S22 and an opening step S24.

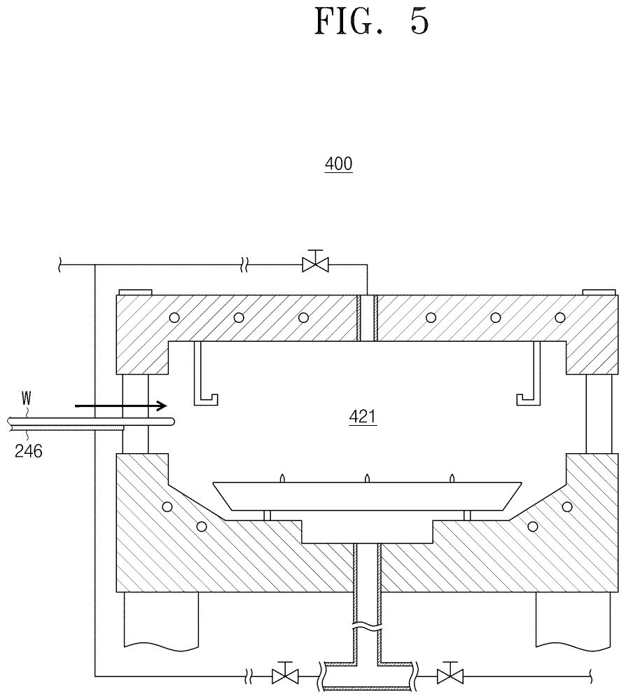

FIGS. 5 to FIG. 11 are views showing a process of treating a substrate in accordance with the steps of the flowchart of FIG. 4 using the drying chamber of FIG. 3. In the figures, a valve with a white inside is an open valve, and a valve with a black inside is a closed valve. Further, solid-line arrows shown in pipes or the treatment space 421 show flow of fluid in the pipes or the treatment space 421, and dotted-line arrows shown in pipes or the treatment space 421 show flow of fluid induced by the pressure of the flow indicated by the solid-line arrows.

The control unit 480 controls the elevation unit 426, the supply unit 440, and the exhaust unit 450 to perform a process of sequentially treating a substrate as follows.

In the loading step S10, a substrate W is loaded into the drying chamber 400. FIG. 5 shows the appearance of the drying chamber when the loading step of FIG. 4 proceeds. Further referring to FIG. 5, in the loading step S10, a substrate W is loaded into the treatment space 421 in the drying chamber 400 by the transfer hand 246 of the transfer unit 244 described above.

After the substrate W is loaded into the treatment space 421 in the drying chamber 400, the lower body 424 is moved up and brought in close contact with the upper body 422, whereby the treatment space 421 is sealed and the discharge step S20 proceeds.

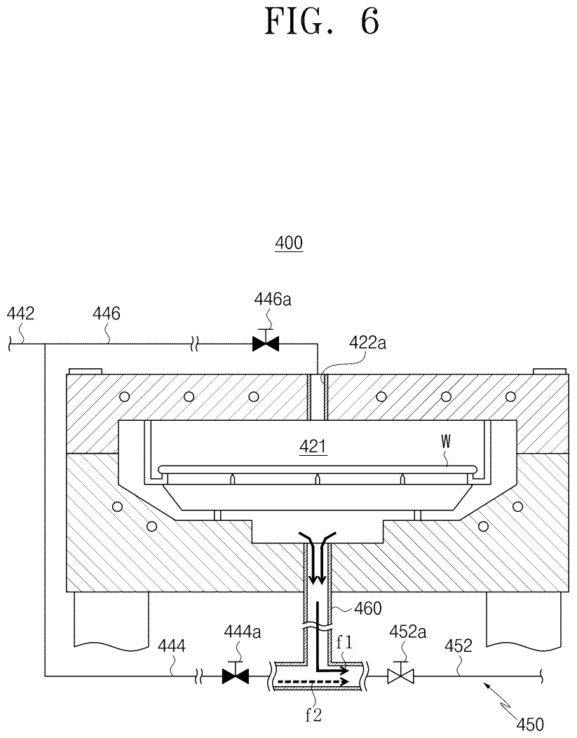

FIG. 6 shows the state of the drying chamber in the pre-opening step of FIG. 4. Referring to FIG. 6, the exhaust valve 452a installed on the exhaust line 452 is opened in the pre-opening step S22. Flow f1 going to the exhaust line 452 from the common pipe 460 is formed, and the atmospheres in the common pipe 460 and the treatment space 421 are exhausted through the exhaust line 452.

Since the flow f1 is formed, the pressure of the common pipe 460 and the exhaust line 452 decreases, and flow f2 going from the first supply line 444 connected with the common pipe 460 to the exhaust line 452 is induced.

The opening step S24 is performed after the pre-opening step S22.

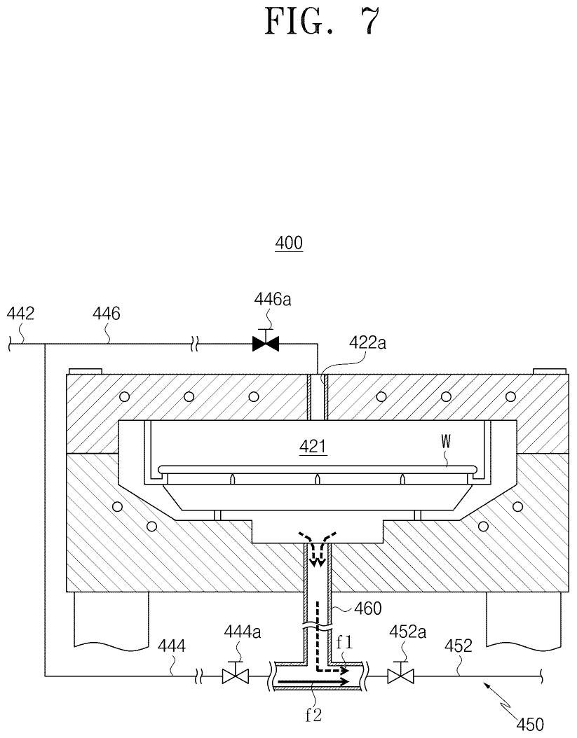

FIG. 7 shows the state of the drying chamber in the opening step of FIG. 4. Referring to FIG. 7, in the opening step S24, the first supply valve 444a installed on the first supply line 444 is opened. Treatment fluid is supplied through the first supply line 444 and the treatment fluid forms flow f2 that is exhausted from the first supply line 444 to the exhaust line 452. Since the flow f2 is formed, the pressure of the first supply line 444 and the exhaust line 452 decreases and flow f1 from the common pipe 460 to the exhaust line 452 is induced.

After the opening step S24, the pressurizing step S30 is performed. In the pressurizing step S30, treatment fluid is supplied to the treatment space 421 such that the internal pressure of the treatment space 421 increases, whereby the pressure of the treatment space 421 is increased up to a setting pressure.

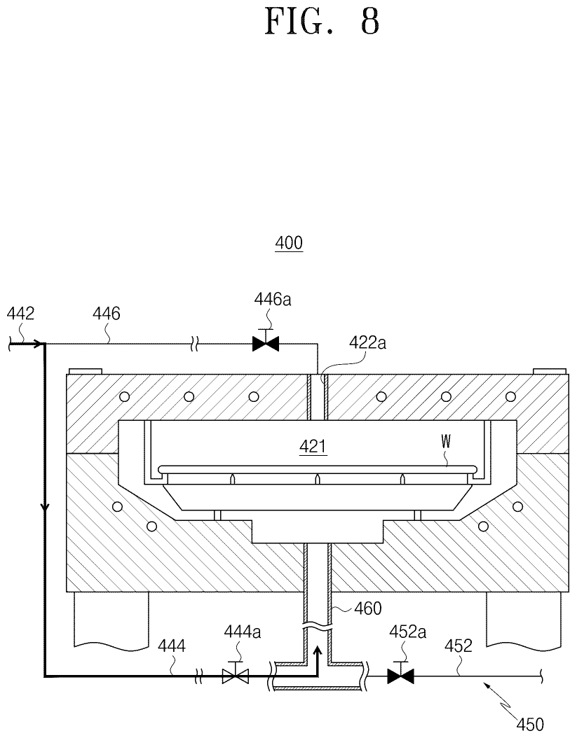

FIGS. 8 to 11 show the state of the drying chamber in the pressurizing step, the depressurizing step, and the unloading step of FIG. 4. Referring to FIG. 8, the exhaust valve 452a installed on the exhaust line 452 is closed in the pressurizing step S30. The treatment fluid that is supplied through the first supply line 444 flows into the treatment space 421 through the common pipe 460.

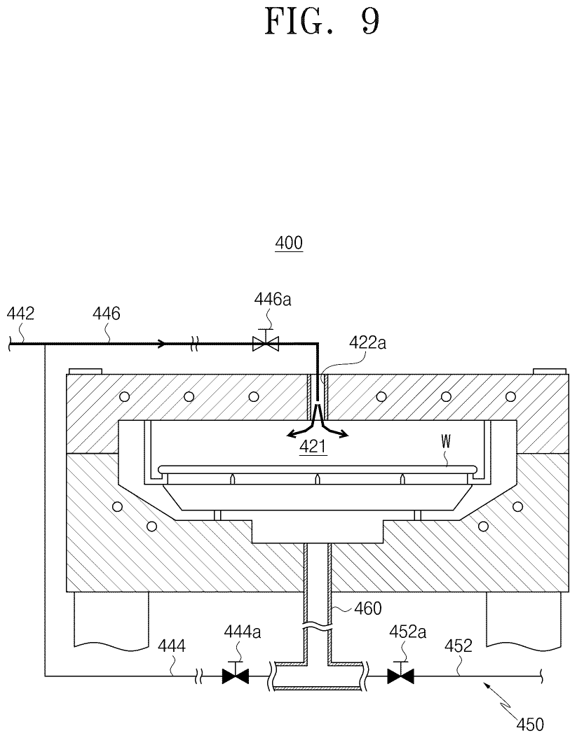

Thereafter, when the inside of the treatment space 421 reaches an appropriate pressure, as shown in FIG. 9, the first supply valve 444a is closed and the second supply valve 446a is opened, whereby the treatment fluid is supplied to the treatment space 421 also through the upper supply port 422a provided in the upper body 422 through the supply line 446.

When the treatment space 421 reaches the setting pressure, the treatment step S40 is performed. The treatment step S40 removes the organic solvent on a substrate W using treatment fluid in the treatment space 421. In the treatment step S40, the internal pressure of the treatment space 421 is repeatedly increased and decreased. When the organic solvent is dissolved in supercritical fluid by a predetermined amount on the substrate W, the organic solvent is discharged through depressurizing and then new supercritical fluid is supplied again to the treatment space, whereby pressurizing is performed.

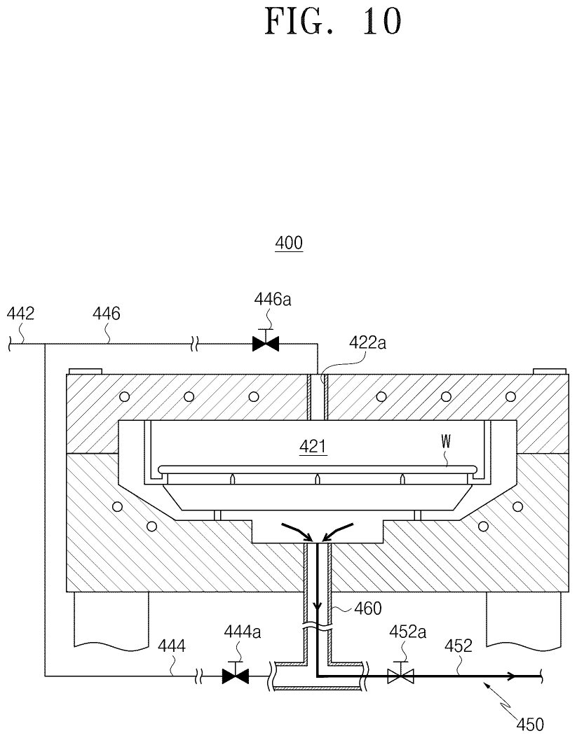

In this case, as shown in FIG. 10, the second supply valve 446a is closed, and when the exhaust valve 452a is opened, the treatment space 421 is depressurized through the common pipe 460. In the treatment step S40, pressurizing and depressurizing can be repeated multiple times while the second supply valve 446a and the exhaust valve 452a are repeatedly opened and closed.

When substrate treatment is finished, the depressurizing step S50 is performed. The depressurizing step S50 decreases the pressure of the treatment space 421 to a second setting pressure by exhausting the atmosphere of the treatment space 421. The second setting pressure may be the atmospheric pressure.

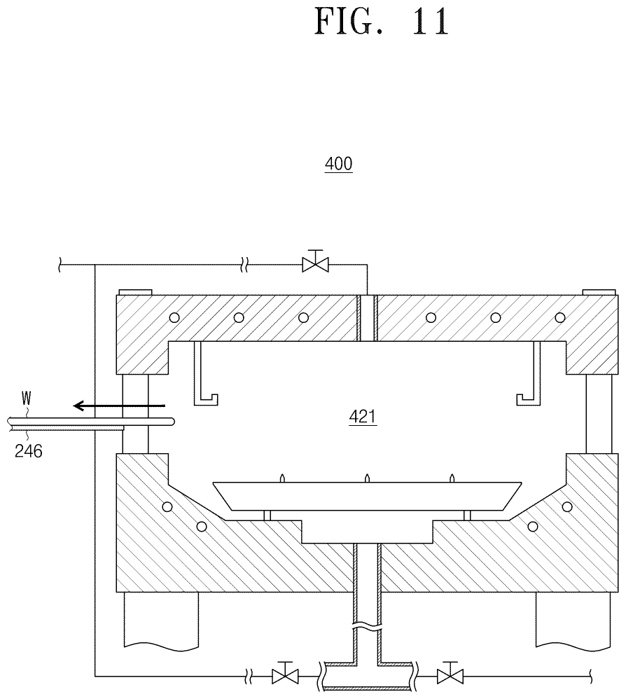

When the depressurizing step S50 is finished, the lower body 424 is moved downward, so the treatment space 421 is opened and the unloading step S60 proceeds. As shown in FIG. 11, in the unloading step S60, the substrate W is unloaded out of the treatment space 421 in the drying chamber 400 by the transfer hand 246 of the transfer unit 244 described above.

The drying chamber 400 can continuously treat a plurality of sheets of substrates W, and, in this process, substances created in the process of treating substrates W and remaining in the treatment fluid and/or on the substrates W (hereafter, referred to as “residues”) may remain in the common pipe 460 and the treatment space 421. Such residues may contaminate substrates W.

The common pipe 460 performs simultaneously the function as a supply passage for supplying treatment fluid supplied from the first supply line 444 to the treatment space 421 and the function of an exhaust passage for exhausting the atmosphere of the treatment space 421 through the exhaust line 452. Since the common pipe 460 is connected to the center portion of the drying chamber 400, that is, the center portion of the lower body 424, it is possible to supply treatment fluid or exhaust the atmosphere of the treatment space 421 at the center potion of the treatment space 421. Accordingly, it is possible to uniformly treat a substrate W.

However, the residues in the common pipe 460 may flow into the treatment space 421 and contaminate a substrate W in the treatment space 421 when treatment fluid is supplied to the treatment space 421 through the first supply line 444 and the common pipe 460 in the pressurizing step S30.

According to an embodiment of the present disclosure, in the pre-opening step S22, flow f1 from the common pipe 460 to the exhaust line 452 is formed and the atmospheres in the common pipe 460 and the treatment space 421 are exhausted by the flow f1. The residues in the common pipe 460 and the treatment space 421 are discharged through the exhaust line 452 and contamination of a substrate W by the residues can be minimized.

As described above, in the pre-opening step S22, the flow f2 is induced by the flow f2, and accordingly, the atmospheres in the common pipe 460 and the treatment space 421 do not flow into the first supply line 444. The residues in the common pipe 460 and the treatment space 421 can be discharged through the exhaust line 452 without contaminating the first supply line 444 due to the flow f2.

As described above, after the pre-opening step S22 proceeds, the opening sep S24 proceeds and the flow f2 keeps being discharged through the exhaust line 452. In this state, the atmospheres in the common pipe 460 and the treatment space 421 also keep being discharged through the exhaust line 452 by the flow f1.

The exhaust valve 452a is opened before the first supply valve 444a is opened, whereby it is possible to primarily discharge the residues in the common pipe 460 and the treatment space 421. Further, the flow f2 going from the first supply line 444 to the exhaust line 452 is induced first using the pressure difference by the flow f1, the flow f2 can be smoothly formed in the opening step S24.

Due to the pressure difference by the flow f2 in the opening step S24, the flow f1 is induced, so it is possible to secondarily discharge the residues in the common pipe 460 and the treatment space 421.

Accordingly, the residues in the common pipe 460 and the treatment space 421 are discharged through the exhaust line 452 and contamination of a substrate W by the residues in the common pipe 460 and the treatment space 421 can be minimized.

In the above example, only the exhaust valve 452a is installed on the exhaust line 452, but the present invention is not limited thereto. A component for smooth exhaust may be additionally installed on the exhaust line 452. For example, a pump may be installed at the downstream side of the exhaust line 452 and the pump can make exhaust from the common pipe 460 and the first supply line 444 smooth.

In the above example, it was described that the first supply line 444 and the second supply line 446 diverge from the main supply line 442 and treatment fluid is sequentially supplied through the first supply line 444 and the second supply line 446. However, unlike this, treatment fluid may be supplied simultaneously through the first supply line 444 and the second supply line 446. Alternatively, the main supply line 442 may not be divided and treatment fluid may be supplied to the treatment space 421 through the common pipe 460.

In the above example, it was described that the second supply line 446 is connected to the supply port 422a formed in the center region of the upper body 422 and supplies treatment fluid. However, unlike this, the second supply line 446 may be coupled to a side of the upper body 422 or the lower body 424 and may supply treatment fluid to the treatment space 421 in parallel with a substrate.

In the above example, it was described that the discharge step S20 is performed every time a substrate W is treated. However, unlike this, discharge step S20 may be performed every time a plurality of sheets of substrates W rather than one substrate W is performed.

In the above example, it was described that the pre-opening step S22 is performed before the first supply valve 444a is opened in the opening step S24, whereby the exhaust valve 452a is opened in advance. However, unlike this, it may be possible to simultaneously open the first supply valve 444a and the exhaust valve 452a. That is, the discharge step S20 may not include the pre-opening step S22. In this case, treatment fluid supplied through the first supply line 444 may be supplied through the common pipe 460 and the residues in the common pipe 460 may contaminate the treatment space 421. In order to prevent this, the present invention may be configured such that the treatment fluid supplied through the first supply line 444 smoothly flows to the exhaust line 452. For example, flow going from the first supply line 444 to the exhaust line 452 may be formed by installing a valve in the common pipe 460 or installing a pump in the exhaust line 452.

In the above example, it was described that the internal pressure of the treatment space 421 is repeatedly increased and decreased in the treatment step S40. Selectively, during the treatment step S40, supercritical fluid may be continuously supplied to the treatment space 421, and simultaneously, the atmosphere in the treatment space 421 may be continuously exhausted.

It should be understood that exemplary embodiments are disclosed herein and that other variations may be possible. Individual elements or features of a particular exemplary embodiment are not generally limited to the particular exemplary embodiment, but are interchangeable and may be used in selected exemplary embodiments, where applicable, even when not specifically illustrated or described. The modifications are not to be considered as departing from the spirit and scope of the present invention, and all such modifications that would be obvious to one of ordinary skill in the art are intended to be included within the scope of the accompanying claims.

1. A substrate processing method, the method comprising:
a loading step of loading a substrate into a treatment space provided in a chamber;
a discharge step of discharging an atmosphere in the treatment space after the loading step;
a pressurizing step of pressurizing the treatment space by supplying treatment fluid to the treatment space after the discharge step;
a treatment step of treating the substrate in the treatment space using a fluid supplied to the treatment space after the pressurizing step; and
a depressurizing step of depressurizing the treatment space after the treatment step.

2. The method of claim 1, wherein a common pipe is connected to the chamber,
the common pipe is connected with a first supply line supplying the treatment fluid to the treatment space and an exhaust line exhausting the atmosphere of the treatment space, and
exhaust of the treatment space is performed through the common pipe in the discharge step.

3. The method of claim 2, wherein the discharge step comprises an opening step of opening an exhaust valve installed on the exhaust line and a first supply valve installed on the first supply line, and
the treatment fluid supplied through the first supply line is discharged to the exhaust line in the opening step.

4. The method of claim 3, wherein the discharge step further comprises a pre-opening step of opening the exhaust valve in advance before the opening step, and
atmospheres of the treatment space and the common pipe are discharged through the exhaust line in the pre-opening step.

5. The method of claim 3, wherein the pressurizing step is performed by closing the exhaust valve and supplying the treatment fluid to the treatment space from the first supply line after the discharge step, and
the treatment fluid is supplied through the common pipe.

6. The method of claim 5, wherein the pressurizing step closes the first supply valve and supplies the treatment fluid to the treatment space through a second supply line connected to the chamber after supplying the treatment fluid to the treatment space from the first supply line.

7. The method of claim 2, wherein exhaust of the treatment space is performed through the common pipe in the depressurizing step.

8. The method of claim 6, wherein the common pipe is connected to a bottom surface of the chamber,
the first supply line is a lower supply line supplying the treatment fluid to a lower portion of the treatment space, and
the second supply line is an upper supply line supplying the treatment fluid to an upper portion of the treatment space.

9. The method of claim 6, wherein the treatment fluid is fluid in a supercritical state, and
the treatment of a substrate is a process of drying a substrate using the fluid in a supercritical state.

10-15. (canceled)

16. A substrate processing method that disposes a substrate into a treatment space provided in a supercritical chamber and treats the substrates by supplying treatment fluid in a supercritical state to the treatment space, the method comprising:
a loading step of loading a substrate into the treatment space;
a discharge step of discharging an atmosphere in the treatment space;
a pressurizing step of pressurizing the treatment space by supplying treatment fluid to the treatment space;
a treatment step of treating the substrate in the treatment space using a fluid supplied to the treatment space; and
a depressurizing step of exhausting the fluid from the treatment space,
wherein a common pipe is connected to the treatment space,
the common pipe is connected with a supply line supplying the treatment fluid to the treatment space and an exhaust line exhausting the atmosphere of the treatment space, and
discharge and exhaust of the treatment space are performed through the common pipe in the discharge step and the depressurizing step.

17. The method of claim 16, wherein the discharge step comprises an opening step of opening an exhaust valve installed on the exhaust line and a supply valve installed on the supply line, and
the treatment fluid supplied through the supply line is discharged to the exhaust line in the opening step.

18. The method of claim 17, wherein the discharge step further comprises a pre-opening step of opening the exhaust valve in advance before the opening step, and
atmospheres of the treatment space and the common pipe are discharged through the exhaust line in the pre-opening step.

19. The method of claim 17, wherein the pressurizing step is performed by closing the exhaust valve and supplying the treatment fluid to the treatment space from the supply line after the discharge step, and
the treatment fluid is supplied through the common pipe.

20. The method of claim 19, wherein the treatment fluid is fluid in a supercritical state, and
the treatment of a substrate is a process of drying the substrate using the fluid in a supercritical state.
